(19) United States
(12) Patent Application Publication
(10) Pub. No.: US 2005/0093090 A1
(43) Pub. Date: May 5, 2005

(54) Semiconductor device and manufacturing method thereof

(75) Inventor: Tomoyuki Shindo, Fujimi-machi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/940,991

(22) Filed: Sep. 15, 2004

(30) Foreign Application Priority Data
Sep. 19, 2003 (JP) 2003-327675

(51) Int. Cl. H01L 29/00

(52) U.S. Cl. 257/528

(57) ABSTRACT

Exemplary embodiments of the present invention provide a semiconductor device that can be produced less costly and a manufacturing method thereof A semiconductor device according to exemplary embodiments of the invention includes an IC chip, an antenna coil formed on an active surface of the IC chip and connected to the IC chip for non-contact data communication, a connecting pad formed on the active surface of the IC chip and connected to one end of the antenna coil, one end of connecting device formed on the active surface of the IC chip and connected to the other end of the antenna coil, and a connecting pad formed on the active surface of the IC chip and connected to the other end of the connecting device. The antenna coil is connected to the internal circuit of the IC chip through the connecting pad, the connecting device, and the connecting pad.

### BACKGROUND OF THE INVENTION

1. Field of Invention

Exemplary embodiments of the present invention relate to a semiconductor device having an antenna coil and a method of producing such a device. More particularly, the exemplary embodiments relate to a semiconductor device having an antenna coil that can be manufactured less costly and a method of producing such a device.

2. Description of Related Art

FIG. 5 is a sectional view of a related art semiconductor device. The semiconductor device is an IC card or an IC tag for use in distribution of commodities.

The semiconductor device has a transparent PET substrate 101 and an antenna coil 102 is provided on the PET substrate 101. The antenna coil is used to carry out non-contact data communication with an external device by electromagnetic induction.

An IC chip 103 that responds to an input from a memory, a CPU and the outside to generate a signal, is provided on the antenna coil 102. The IC chip 103 modulates specific information in the memory and outputs the information from the antenna coil when it responds to an external device by non-contact communication. The IC chip 103 has its active surface positioned to oppose the antenna coil 102. The IC chip 103 is provided with bumps 104 and 105 on its active surface, and the bumps 104 and 105 are electrically connected to a semiconductor circuit in the IC chip.

The bump 104 is connected to one end of the antenna coil 102 through a conductive adhesive 106. The bump 105 is connected to the other end of the antenna coil 102 through the conductive adhesive 106.

Now, a method of producing the related art semiconductor device shown in FIG. 5 will be described.

A metal foil is provided on the surface of the PET substrate 101 with an adhesive (not shown). Then, in order to form an antenna coil pattern on the metal foil, etching resistant resist (not shown) is applied by screen printing or the like on a part to leave interconnection. The substrate is then immersed in an agent such as ferric chloride for etching the metal foil. In this way, the antenna coil 102 in a helical pattern is formed on the PET substrate 101.

Then, an IC chip 103 that generates a signal in response to an input from a memory, a CPU, and the outside, is prepared. Bumps 104 and 105 are formed on the active surface of the IC chip 103.

The IC chip 103 is then provided on the antenna coil 102, and the bump 104 on the IC chip 103 is electrically connected to one end of the antenna coil 102 through the conductive adhesive 106. The bump 105 on the IC chip 103 is electrically connected to the other end of the antenna coil 102 through the conductive adhesive 106. By this process, the semiconductor device as shown in FIG. 5 is formed.

### SUMMARY OF THE INVENTION

In the related art semiconductor device as described above, the antenna coil 102 is formed on the PET substrate 101 and the IC chip 103 is bonded on the antenna coil 102 by flip-chip bonding. The manner of forming the antenna coil and bonding the IC chip necessitates the use of very expensive devices, which increases the manufacturing cost.

Exemplary embodiments of the present invention are directed to a solution for the above discussed and/or other problems. Exemplary embodiments of the invention provide a semiconductor device that can be manufactured less costly and a manufacturing method thereof.

In order to address or solve the above described and/or other problems, a semiconductor device according to exemplary embodiments of the invention includes an IC chip, and an antenna coil formed on an active or back surface of the IC chip and connected to the internal circuit of the IC chip for non-contact data communication.

In the semiconductor device, an antenna coil is formed on an active or back surface of the IC chip, flip-chip bonding to the substrate is not necessary unlike the related art semiconductor device. Accordingly, simply by using the IC chip, the device may function as an IC card or an IC tag for use in distribution of commodities. Consequently, the manufacturing cost can be reduced.

A semiconductor device according to exemplary embodiments of the invention includes an IC chip, an antenna coil formed on an active surface of the IC chip and connected to the IC chip for non-contact data communication, a first pad formed on the active surface of the IC chip and connected to one end of the antenna coil, one end of a connecting device formed on the active surface of the IC chip and connected to the other end of the antenna coil, and a second pad formed on the active surface of the IC chip and connected to the other end of the connecting device. The antenna coil is connected to the internal circuit of the IC chip through the first pad, the connecting device, and the second pad.

A semiconductor device according to the exemplary embodiments of invention includes an IC chip, an antenna coil formed on a back surface of the IC chip and connected to the IC chip for non-contact data communication, a first through hole connected to one end of the antenna coil and formed in the IC chip, one end of a connecting device formed on the back surface of the IC chip and connected to the other end of the antenna coil, and a second through hole connected to the other end of the connecting device and formed in the IC chip. The antenna coil is connected to the internal circuit of the IC chip through the first through hole, the connecting device, and the second through hole.

A semiconductor device according to exemplary embodiments of the invention includes a flexible substrate, an IC chip fixed on the flexible substrate, and an antenna coil formed on an active or back surface of the IC chip and connected to the internal circuit of the IC chip for non-contact data communication.

In the semiconductor device, an antenna coil is formed on an active or back surface of the IC chip, therefore flip-chip bonding to the flexible substrate is not necessary unlike the related art device, and the IC chip needs only be fixed to the flexible substrate. Consequently, the manufacturing cost can be reduced.

A semiconductor device according to exemplary embodiments of the invention includes a card substrate, a recess provided at a surface of the card substrate, an IC chip fitted into the recess, an antenna coil formed on an active or back surface of the IC chip and connected to the internal circuit of the IC chip for non-contact data communication, and a protection film attached on the IC chip and the card substrate.

A method of producing a semiconductor device according to exemplary embodiments of the invention includes forming a semiconductor circuit on a semiconductor substrate, forming a passivation film on the upper side of the semiconductor substrate, and forming an antenna coil for non-contact data communication on the passivation film. The antenna coil is connected to the semiconductor circuit.

By the exemplary method of producing the semiconductor device, an antenna coil is formed on the passivation film and therefore, general semiconductor process may be applied to form the antenna coil. Therefore, the antenna coil may be produced less costly than the related art product. Since the antenna coil is provided on the passivation film, flip-chip bonding to the substrate is not necessary unlike the related art semiconductor device. Therefore, the manufacturing cost can be reduced.

In the exemplary method of producing a semiconductor device, the antenna coil may have its one end connected to the semiconductor circuit through a first pad and its other end connected to the semiconductor circuit through a connecting device and a second pad.

In the method of producing a semiconductor device according to exemplary embodiments of the invention, in forming the antenna coil, a metal film may be formed on the passivation film and patterned to form an antenna coil made of the metal film on the passivation film.

In the method of producing a semiconductor device according to exemplary embodiments of the invention, in forming an antenna coil, the antenna coil made of a metal film may be formed on the passivation film using an inkjet mechanism.

In the method of producing a semiconductor device according to exemplary embodiments of the invention, in forming the antenna coil, a groove in an antenna coil pattern may be formed in the passivation film, a metal film may be formed in the groove and on the passivation film, and the metal film may be polished by CMP. Accordingly, the metal film located on the passivation film is removed and an antenna coil made of the metal film is formed in the groove in the passivation film.

In a method of producing a semiconductor device according to exemplary embodiments of the invention includes forming a semiconductor circuit at a semiconductor substrate, forming first and second through holes in the semiconductor substrate, and forming an antenna coil for non-contact data communication on a back surface of the semiconductor substrate. The antenna coil has one end electrically connected to the semiconductor circuit through the first through hole and another end electrically connected to the semiconductor circuit through the second through hole.

A method of producing a semiconductor device according to exemplary embodiments of the invention includes preparing an IC chip having an antenna coil for non-contact data communication formed on its active or back surface, and fixing the IC chip on a flexible substrate.

In a method of producing a semiconductor device according to exemplary embodiments of the invention includes preparing an IC chip having an antenna coil for non-contact data communication formed on its active or back surface, preparing a card substrate having a recess at its surface, fitting the IC chip into the recess at the card substrate, and attaching a protection film on the IC chip and the card substrate.

### BRIEF DESCRIPTION OF THE DRAWINGS

FIG. 1A is a schematic plan view of a semiconductor device according to a first exemplary embodiment of the invention;

FIG. 1B is a schematic sectional view of the semiconductor device;

FIG. 2 is a schematic sectional view of a semiconductor device according to a second exemplary embodiment of the invention;

FIG. 3 is a schematic sectional view of a semiconductor device according to a third exemplary embodiment of the invention;

FIG. 4A is a schematic plan view of a semiconductor device according to a fourth exemplary embodiment of the invention;

FIG. 4B is a schematic sectional view of the semiconductor device; and

FIG. 5 is a schematic sectional view of a related art semiconductor device.

### DETAILED DESCRIPTION OF PREFERRED EMBODIMENTS

Now, exemplary embodiments of the invention will be described in conjunction with the accompanying drawings.

### First Exemplary Embodiment

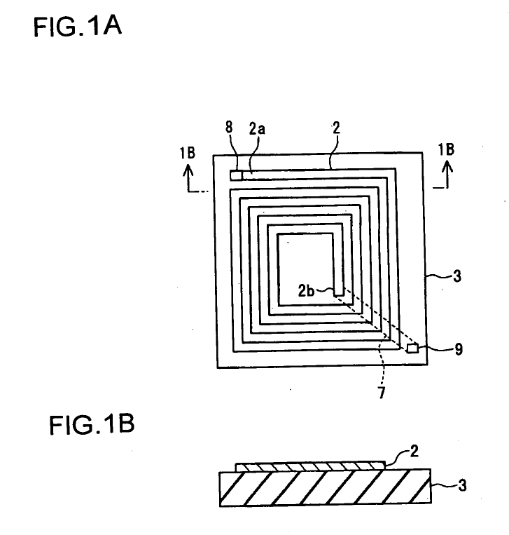

FIG. 1A is a schematic plan view of a semiconductor device according to a first exemplary embodiment of the invention and FIG. 1B is a schematic sectional view taken along line 1B-1B in FIG. 1A. The semiconductor device includes an IC chip.

As shown in FIGS. 1A and 1B, an antenna coil 2 for non-contact data communication with an external device by electromagnetic induction, is formed on a passivation film at an active surface of the IC chip 3. The antenna coil 2 is formed in a helical shape from the outer peripheral side of the IC chip 3 to the center. One end 2a of the antenna coil 2 is connected with a connecting pad 8. The other end 2b of the antenna coil 2 is connected with one end of a connecting device 7, and the other end of the connecting device 7 is connected with a connecting pad 9. Various kinds of connecting device can be used as the connecting device 7 as long as they can electrically connect the end 2b of the antenna coil 2 and the connecting pad 9. The connecting pads 8 and 9 may be made of an Al or Al alloy film or a Au—Sn alloy.

The IC chip 3 can generate a signal in response to an input from a memory, a CPU, and the outside. When the IC chip 3 responds by non-contact communication with an external device, the IC chip modulates specific information in the memory and outputs the modulated information from the antenna coil 2. The connecting pads 8 and 9 are electrically connected with the semiconductor device in the IC chip.

Now, an exemplary method of producing the semiconductor device shown in FIG. 1 will be described.

A semiconductor circuit that generates a signal in response to an input from the memory, the CPU, and the outside is provided in each of a plurality of IC chip regions in a wafer (silicon substrate). Then, a passivation film as the uppermost layer on the wafer is formed and then a metal film made of Cu, Al, a Cu alloy, or an Al alloy is formed by sputtering on the passivation film. The metal film is coated with a photoresist film. Then, the photo resist film is exposed to light and developed, so that a resist pattern is formed on the metal film. The resist pattern is formed only at a part to leave interconnection in order to form an antenna coil pattern.

Then, using the resist pattern as a mask, an antenna coil 2 in a helical pattern as shown in FIG. 1A, is formed on the passivation film. In this way, one end 2a of the antenna coil 2 is connected with the connecting pad 8, the other end 2b of the antenna coil 2 is connected with one end of the connecting device 7, and the other end of the connecting device 7 is connected with the connecting pad 9. More specifically, the end 2b of the antenna coil 2 and the connecting pad 9 are electrically connected by the connecting device 7.

Then, the wafer is divided into IC chips. In this way, the semiconductor device shown in FIG. 1A is formed.

According to the first exemplary embodiment described above, the antenna coil 2 is provided on the passivation film for the IC chip 3, and therefore flip-chip bonding with the PET substrate is not necessary unlike the related art semiconductor device. Accordingly, simply by using the IC chip 3, the device may function as an IC card or an IC tag for use in distribution of commodities. The necessity of the flip-chip bonding is eliminated and the manufacturing cost can be reduced. The antenna coil 2 is formed on the passivation film for the IC chip 3, and therefore the antenna coil 2 can be formed by general semiconductor process. Consequently, the antenna coil can be formed less costly than the related art product.

Note that according to the first exemplary embodiment, the metal film is formed on the passivation film by sputtering a metal film and the metal film is patterned by photolithography and etching. In this way, the antenna coil 2 is formed on the active surface of the IC chip 3. Meanwhile, the process of forming the antenna coil may be embodied by being modified as follows.

An antenna coil pattern of a metal can be formed on the passivation film using an ink jet mechanism.

The passivation film may be provided with a groove in an antenna coil pattern, and a metal film may be formed in the groove and on the passivation film by sputtering. Then, the metal film may be polished by CMP (Chemical Mechanical Polishing), so that the metal film located on the passivation film is removed and the antenna coil of the metal film may be formed in the groove in the passivation film.

### Second Exemplary Embodiment

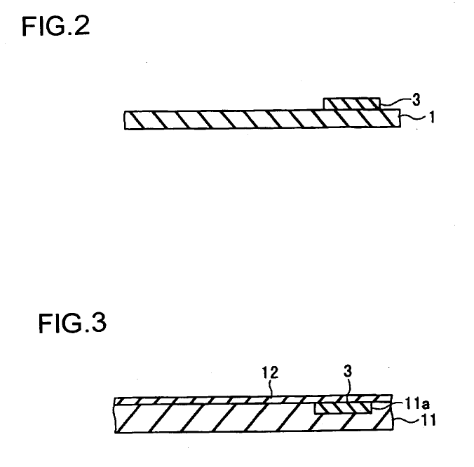

FIG. 2 is a schematic sectional view of a semiconductor device according to a second exemplary embodiment of the invention. According to the second exemplary embodiment, the semiconductor device forms an IC tag for use in distribution of commodities.

The semiconductor device is formed by attaching an IC chip 3 on a flexible substrate such as a PET substrate 1 having an antenna coil as shown in FIGS. 1A and 1B by an adhesive (not shown).

According to the second exemplary embodiment, the same or similar effect as the first exemplary embodiment may be provided.

More specifically, since the antenna coil 2 is provided on the passivation film for the IC chip 3, flip-chip bonding to the PET substrate is not necessary unlike the related art semiconductor device. The IC chip 3 needs only be attached to the PET substrate 1. Therefore, the manufacturing cost can be reduced. The antenna coil 2 is formed on the passivation film for the IC chip 3 and can therefore be formed by general semiconductor process. Consequently, the antenna coil can be produced less costly than the related art product.

### Third Exemplary Embodiment

FIG. 3 is a schematic sectional view of a semiconductor device according to a third exemplary embodiment of the invention. The semiconductor device forms an IC card.

A card substrate 11 having a recess (dent) 11a on its surface to fit in an IC chip 3, is prepared. The IC chip 3 is fitted into the recess 11a of the card substrate 11 and the IC chip and the card substrate are fixed by an adhesive (not shown).

A protection film 12 to protect the IC chip 3 is provided on the surface of the card substrate 11. The protection film 12 is fixed to the card substrate by an adhesive (not shown). In this way, the IC card is produced.

According to the third exemplary embodiment, the same or similar effect as the first exemplary embodiment can be provided.

More specifically, since the antenna coil 2 is provided on the passivation film for the IC chip 3, and therefore flip-chip bonding to the substrate is not necessary unlike the related art semiconductor device. The IC card can be produced by fixing the IC chip 3 to the card substrate 11 by the adhesive. Consequently, the manufacturing cost can be reduced. The antenna coil can be produced by general semiconductor process and can therefore be produced less costly than the related art product.

### Fourth Exemplary Embodiment

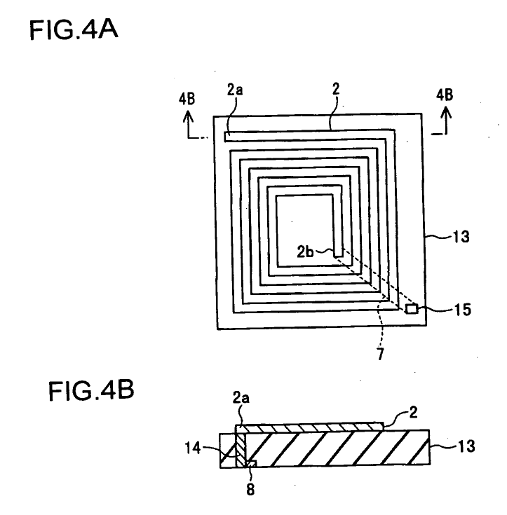

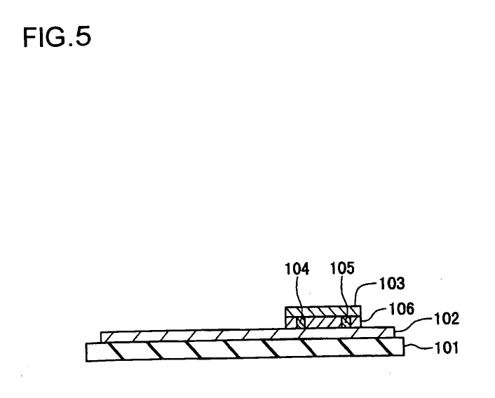

FIG. 4A is a schematic plan view of a semiconductor device according to a fourth exemplary embodiment of the invention, and FIG. 4B is a schematic sectional view taken along line 4B-4B in FIG. 4A. The semiconductor device includes an IC chip.

As shown in FIGS. 4A and 4B, an insulating film that is not shown, is formed on the back surface of the IC chip 13 (on the opposite side to the active surface), and an antenna coil 2 for non-contact data communication with an external device by electromagnetic induction, is formed on the insulating film. The antenna coil 2 is formed in a helical shape from the outer peripheral side of the back surface of the IC chip 13 to the center. There is a through hole 14 under one end 2a of the antenna coil 2, and a conductive film fills the through hole 14.

The through hole 14 has its upper end connected to the end 2a of the antenna coil 2 and its lower end connected to a connecting pad 8. The connecting pad 8 is formed on the active surface (surface) of the IC chip 13. The other end 2b of the antenna coil 2 is connected with one end of the connecting device 7, and the other end of the connecting device 7 is connected with a through hole 15. The lower end of the through hole 15 is connected to a connecting pad that is not shown. A conductive film fills the through hole 15.

Various kinds of connecting device can be used as the connecting device 7 as long as they can electrically connect the end 2b of the antenna coil 2 and the connecting pad 9. The connecting pad 8 may be made of an Al or Al alloy film or a Au—Sn alloy. The IC chip 3 can generate a signal in response to an input from a memory, a CPU, and the outside. When the IC chip 3 responds by non-contact communication with an external device, specific information in the memory is modulated and output from the antenna coil 2. The connecting pad 8 is electrically connected to a semiconductor circuit in the IC chip.

Now, an exemplary method of producing the semiconductor device shown in FIG. 4 will be described.

A semiconductor circuit that generates a signal in response to an input from a memory, a CPU, and the outside is formed in each of a plurality of IC chip regions in a wafer (silicon substrate). Then, a passivation film as the uppermost layer on the wafer is formed, through holes 14 and 15 are formed in the IC chip 13, and then a conductive film fills the through holes 14 and 15.

A metal film for example of Cu, Al, a Cu alloy or an Al alloy is formed by sputtering on the back surface of the wafer (on the opposite side to the active surface) with an insulating film therebetween. Then, a photoresist film is applied on the metal film, and the photoresist film is exposed to light and developed to form a resist pattern on the metal film. The resist pattern is formed only at the part to leave interconnection to form an antenna coil pattern.

Then, using the resist pattern as a mask, the metal film is etched to form an antenna coil 2 in a helical pattern on the insulating film as shown in FIG. 4A. The antenna coil 2 has one end 2a connected with the upper end of the through hole 14, and the lower end of the through hole 14 is connected with a connecting pad 8. The other end 2b of the antenna coil 2 is connected with one end of connecting device 7. The other end of the connecting device 7 is connected with the upper end of the through hole 15, and the lower end of the through hole 15 is connected with a connecting pad.

The wafer is divided into IC chips. In this way, the semiconductor device as shown in FIG. 4A is formed.

According to the fourth exemplary embodiment of the invention, the antenna coil 2 is provided on the back surface of the IC chip 13 with an insulating film therebetween, and therefore flip-chip bonding to the PET substrate is not necessary unlike the related art semiconductor device. By using the IC chip 13, the device may function as the IC card or the IC tag for use in distribution of commodities. More specifically, since the flip-chip bonding is not necessary, the manufacturing cost can be reduced. The antenna coil 2 is formed on the back surface of the IC chip 13 with an insulating film therebetween. Therefore, the antenna coil 2 can therefore be produced by general semiconductor process. Consequently, the antenna coil can be produced less costly than the related art product.

According to the fourth exemplary embodiment, a metal film is formed by sputtering on the back surface of the IC chip with an insulating film therebetween, and the metal film is patterned by photolithography or etching to form the antenna coil 2 on the back surface of the IC chip 13, but the process of producing the antenna coil may be embodied by as follows.

An antenna coil pattern of a metal can be formed on the back surface of the IC chip using an ink jet mechanism with an insulating film therebetween.

The insulating film may be provided with a groove in an antenna coil pattern, and a metal film may be formed in the groove and on the insulating film by sputtering. Then, the metal film may be polished by CMP, so that the metal film on the insulating film is removed and the antenna coil of the metal film may be formed in the groove in the insulating film.

The IC chip 13 having the antenna coil as shown in FIG. 4 may be fixed on the PET substrate 1 in FIG. 2 by an adhesive, and a semiconductor device as an IC tag may be produced.

Alternatively, the IC chip 13 having the antenna coil as shown in FIG. 4, may be fitted into the recess 11a of the card substrate 11 as shown in FIG. 3, and a protection film 12 may be formed on the IC chip 13 and the card substrate 11. In this way, a semiconductor device as an IC card may be produced.

The present invention is not limited to the exemplary embodiments described above and various exemplary modifications can be carried out without departing and scope of the invention.

1. A semiconductor device, comprising:
an IC chip having an internal circuit; and
an antenna coil formed on at least one of an active and a back surface of the IC chip and connected to the internal circuit of the IC chip for non-contact data communication.

2. A semiconductor device, comprising:
an IC chip having an active surface;
an antenna coil formed on the active surface of the IC chip and connected to the IC chip for non-contact data communication;
a first pad formed on the active surface of the IC chip and connected to one end of the antenna coil;
one end of a connecting device formed on the active surface of the IC chip and connected to a other end of the antenna coil; and
a second pad formed on the active surface of the IC chip and connected to the other end of the connecting device,
the antenna coil being connected to an internal circuit of the IC chip through the first pad, the connecting device, and the second pad.

3. A semiconductor device, comprising:
an IC chip having an internal circuit;
an antenna coil formed on a back surface of the IC chip and connected to the IC chip for non-contact data communication;
a first through hole connected to one end of the antenna coil and formed in the IC chip;
one end of a connecting device formed on the back surface of the IC chip and connected to a other end of the antenna coil; and
a second through hole connected to the other end of the connecting device and formed in the IC chip,
the antenna coil being connected to the internal circuit of the IC chip through the first through hole, the connecting device, and the second through hole.

4. A semiconductor device, comprising:
a flexible substrate;
an IC chip fixed on the flexible substrate; and
an antenna coil formed on at least one of an active and a back surface of the IC chip and connected to an internal circuit of the IC chip for non-contact data communication.

5. A semiconductor device, comprising:
a card substrate;
a recess provided at a surface of the card substrate;
an IC chip fitted into the recess;
an antenna coil formed on at least one of an active and a back surface of the IC chip and connected to the internal circuit of an IC chip for non-contact data communication; and
a protection film attached on the IC chip and the card substrate.

6. A method of producing a semiconductor device, comprising:
forming a semiconductor circuit on a semiconductor substrate;
forming a passivation film on an upper side of the semiconductor substrate; and
forming an antenna coil for non-contact data communication, on the passivation film,
the antenna coil being connected to the semiconductor circuit.

7. The method of producing a semiconductor device according to claim 6, the antenna coil having one end connected to the semiconductor circuit through a first pad and a other end connected to the semiconductor circuit through a connecting device and a second pad.

8. The method of producing a semiconductor device according to claim 6, in forming an antenna coil, a metal film being formed on the passivation film, and the metal film being patterned to form an antenna coil made of the metal film on the passivation film.

9. The method of producing a semiconductor device according to claim 6, in forming an antenna coil, an antenna coil made of a metal film being formed on the passivation film using an inkjet mechanism.

10. The method of producing a semiconductor device according to claim 6, in forming an antenna coil, a groove in an antenna coil pattern being formed in the passivation film, a metal film being formed in the groove and on the passivation film, and the metal film being polished by CMP, so that the metal film located on the passivation film is removed and an antenna coil made of the metal film is formed in the groove in the passivation film.

11. A method of producing a semiconductor device, comprising:
forming a semiconductor circuit in a semiconductor substrate;
forming first and second through holes in the semiconductor substrate; and
forming an antenna coil for non-contact data communication, on a back surface of the semiconductor substrate,
the antenna coil having one end electrically connected to the semiconductor circuit through the first through hole and a other end electrically connected to the semiconductor circuit through the second through hole.

12. A method of producing a semiconductor device, comprising:
preparing an IC chip having an antenna coil for non-contact data communication formed on at least one of an active and a back surface of the IC chip; and
fixing the IC chip on a flexible substrate.

13. A method of producing a semiconductor device, comprising:
preparing an IC chip having an antenna coil for non-contact data communication formed on at least one of an active and a back surface of the IC chip; and
preparing a card substrate having a recess at its surface;
fitting the IC chip into the recess at the card substrate; and
attaching a protection film on the IC chip and the card substrate.
